(19) United States
(12) Patent Application Publication
(10) Pub. No.: US 2025/0054733 A1
(43) Pub. Date: Feb. 13, 2025

(54) APPARATUS FOR PROCESSING A SUBSTRATE

(71) Applicant: Samsung Electronics Co., Ltd., Suwon-si (KR)

(72) Inventors: Yirop Kim, Suwon-si (KR); Seungbin Lim, Suwon-si (KR); Songyun Kang, Suwon-si (KR); Kyungsun Kim, Suwon-si (KR); Kuihyun Yoon, Suwon-si (KR); Jihwan Kim, Suwon-si (KR); Heewon Min, Suwon-si (KR); Insoo Lee, Suwon-si (KR); Junho Lee, Suwon-si (KR); Seunghee Cho, Suwon-si (KR)

(21) Appl. No.: 18/424,996

(22) Filed: Jan. 29, 2024

(30) Foreign Application Priority Data
Aug. 9, 2023 (KR) 10-2023-0103926

(51) Int. Cl. H01J 37/32

(52) U.S. Cl. CPC H01J 37/32449; H01J 37/32568

(57) ABSTRACT

An apparatus for processing a substrate may include a process chamber, a substrate-supporting module, an upper electrode module and a valve module. The process chamber may have a substrate-processing region configured to process the substrate using process gases. The substrate-supporting module may be arranged in a lower region of the process chamber to support the substrate. The upper electrode module may be arranged in an upper region of the process chamber. The valve module may be provided to the upper electrode module to control a supplying of the process gases into the substrate-processing region.

### CROSS-REFERENCE TO RELATED APPLICATIONS

This application claims priority under 35 USC § 119 to Korean Patent Application No. 10-2023-0103926, filed on Aug. 9, 2023 in the Korean Intellectual Property Office (KIPO), the content of which is herein incorporated by reference in its entirety.

### BACKGROUND

### 1. Field

Example embodiments relate to an apparatus for processing a substrate. More particularly, example embodiments relate to an apparatus for processing a semiconductor substrate using process gases.

### 2. Description of the Related Art

Generally, an apparatus for processing a substrate may process the substrate using plasma generated from process gases. For example, the apparatus may form a layer on the substrate or etch a layer on the substrate using the plasma. Thus, the process gases may be introduced into a process chamber of the apparatus.

According to related arts, the process gases in a gas tank may be supplied into the apparatus through a valve. The valve may be positioned outside the apparatus. Thus, a very long path may be formed between the valve and the apparatus. The long path may increase a volume of the path and also generate a flow resistance. The volume of the path and the flow resistance may extend the time period for exhausting the process gases used in a previous process from the apparatus. This may result in process non-uniformity and low productivity.

### SUMMARY

Example embodiments provide an apparatus for processing a substrate that may be capable of decreasing a path of process gases.

According to example embodiments, there may be provided an apparatus for processing a substrate. The apparatus may include a process chamber, a substrate-supporting module, an upper electrode module and a valve module. The process chamber may have a substrate-processing region configured to process the substrate using process gases. The substrate-supporting module may be arranged in a lower region of the process chamber to support the substrate. The upper electrode module may be arranged in an upper region of the process chamber. The valve module may be provided to the upper electrode module to control a supplying of the process gases into the substrate-processing region.

According to example embodiments, there may be provided an apparatus for processing a substrate. The apparatus may include a process chamber, a substrate-supporting module, an upper electrode module and a valve module. The process chamber may have a substrate-processing region configured to process the substrate using process gases. The substrate-supporting module may be arranged in a lower region of the process chamber to support the substrate. The upper electrode module may be arranged in an upper region of the process chamber. The valve module may be provided to the upper electrode module to control a supplying of the process gases into the substrate-processing region. The valve module may include a valve block, a flexible valve stem and a control line. The valve block may include a plurality of inlets, a plurality of outlets and gas passages. The process gases may be introduced into the inlets. The outlet may inject the process gases into the substrate-processing region. The gas passages may be connected between the inlets and the outlets. The flexible valve stem may be arranged in each of the gas passages to open and close the inlet. The control line may provide the flexible valve stem with a working fluid to expand the flexible valve stem toward the inlet.

According to example embodiments, there may be provided an apparatus for processing a substrate. The apparatus may include a process chamber, a substrate-supporting module, an upper electrode module and a valve module. The process chamber may have a substrate-processing region configured to process the substrate using process gases. The substrate-supporting module may be arranged in a lower region of the process chamber to support the substrate. The upper electrode module may be arranged in an upper region of the process chamber. The valve module may be provided to the upper electrode module to control a supplying of the process gases into the substrate-processing region. The valve module may include a valve block, a permanent magnet and an electromagnet. The valve block may include a plurality of inlets, a plurality of outlets and gas passages. The process gases may be introduced into the inlets. The outlet may inject the process gases into the substrate-processing region. The gas passages may be connected between the inlets and the outlets. The permanent magnet may be movably arranged in each of the gas passages to open and close the inlet. The electromagnet may selectively apply a repulsive force and an attractive force to the permanent magnet.

According to example embodiments, the valve module may be provided to the substrate-processing region of the apparatus, particularly, the upper electrode module. Thus, a length between the valve module and the apparatus, particularly, between the valve module and the substrate-processing region, i.e., a path of the process gases may be shortened. Particularly, the time period in which the process gases traverse the path of the process gases may be decreased. Thus, a volume of the path and a flow resistance may be reduced to rapidly exhaust the process gases used in a previous process from the apparatus. As a result, process uniformity and productivity may be improved.

### BRIEF DESCRIPTION OF THE DRAWINGS

Example embodiments will be more clearly understood from the following detailed description taken in conjunction with the accompanying drawings. FIGS. 1 to 20 represent non-limiting, example embodiments as described herein.

FIG. 1 is a cross-sectional view illustrating an apparatus for processing a substrate in accordance with example embodiments;

FIG. 2 is an enlarged cross-sectional view illustrating a valve module provided to an upper electrode module of the apparatus in FIG. 1;

FIGS. 3 and 4 are perspective views illustrating an operation of the valve module in FIG. 2;

FIG. 5 is a cross-sectional view illustrating a valve module in accordance with example embodiments;

FIG. 6 is a cross-sectional view illustrating an apparatus for processing a substrate in accordance with example embodiments;

FIG. 7 is an enlarged cross-sectional view illustrating a valve module provided to an upper electrode module of the apparatus in FIG. 6;

FIGS. 8 and 9 are perspective views illustrating an operation of the valve module in FIG. 7;

FIG. 10 is a cross-sectional view illustrating a valve module in accordance with example embodiments;

FIG. 11 is a cross-sectional view illustrating an apparatus for processing a substrate in accordance with example embodiments;

FIG. 12 is a cross-sectional view illustrating an apparatus for processing a substrate in accordance with example embodiments;

FIG. 13 is a cross-sectional view illustrating an apparatus for processing a substrate in accordance with example embodiments;

FIG. 14 is a cross-sectional view illustrating an apparatus for processing a substrate in accordance with example embodiments;

FIG. 15 is a cross-sectional view illustrating an apparatus for processing a substrate in accordance with example embodiments;

FIG. 16 is a cross-sectional view illustrating an apparatus for processing a substrate in accordance with example embodiments;

FIG. 17 is a cross-sectional view illustrating an apparatus for processing a substrate in accordance with example embodiments;

FIG. 18 is a cross-sectional view illustrating an apparatus for processing a substrate in accordance with example embodiments;

FIG. 19 is a cross-sectional view illustrating an apparatus for processing a substrate in accordance with example embodiments; and

FIG. 20 is a cross-sectional view illustrating an apparatus for processing a substrate in accordance with example embodiments.

### DETAILED DESCRIPTION OF THE EMBODIMENTS

Hereinafter, example embodiments will be explained in detail with reference to the accompanying drawings.

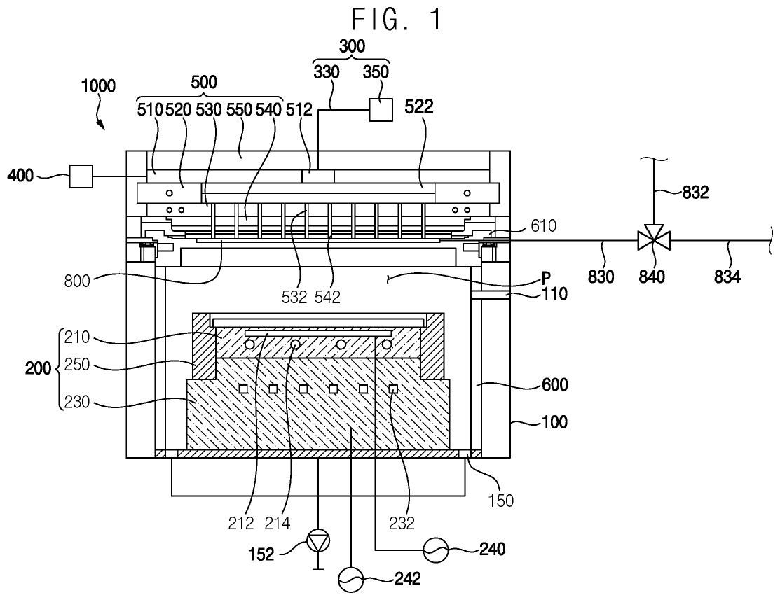

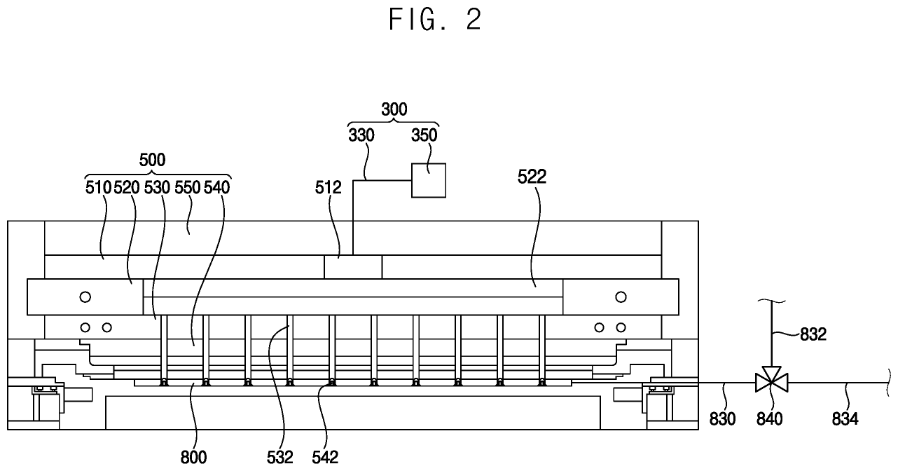

FIG. 1 is a cross-sectional view illustrating an apparatus for processing a substrate in accordance with example embodiments and FIG. 2 is an enlarged cross-sectional view illustrating a valve module provided to an upper electrode module of the apparatus in FIG. 1.

Referring to FIGS. 1 and 2, an apparatus 1000 for processing a substrate in accordance with example embodiments may include a process chamber 100, a substrate-supporting module 200, a gas-supply module 300, an upper electrode module 500, a liner 600 and a valve module 800.

The process chamber 100 may be configured to receive the substrate. The substrate may include a semiconductor substrate, a glass substrate, etc. The process chamber 100 may have a substrate-processing region P. The substrate-processing region P may be positioned between the upper electrode module 500 and the substrate-supporting module 200. For example, plasma may be generated in the substrate-processing region P from process gases. The process chamber 100 may have a cylindrical shape, but not limited thereto. For example, the process chamber 100 may have a rectangular parallelepiped shape.

The process chamber 100 may include a shutter 110. The shutter 110 may be arranged at a sidewall of the process chamber 100. The substrate may be loaded/unloaded into/from the process chamber 100 through the shutter 110. The process chamber 100 may include a metal, but not limited thereto.

The liner 600 may be arranged on an inner wall of the process chamber 100. The liner 600 may suppress damage to the process chamber 100 caused by power of the plasma, particularly, an RF power of the plasma. The liner 600 may make contact with the inner wall of the process chamber 100.

The liner 600 may include a flange 610. The flange 610 may be integrally formed with an upper edge portion of the liner 600. The flange 610 may have a lower surface combined with an upper end of the sidewall of the process chamber 100.

An exhaust hole 150 may be formed through a bottom surface of the process chamber 100. The exhaust hole 150 may be connected with an exhaust pump 152 through an exhaust line. The exhaust pump 152 may provide the exhaust hole 150 with a vacuum through the exhaust line. Byproducts generated in a process and the plasma in the process chamber 100 may be exhausted from the process chamber 100 by the vacuum provided from the exhaust pump 152.

The substrate-supporting module 200 may be arranged on the bottom surface of the process chamber 100 to support the substrate. The substrate-supporting module 200 may include an electrostatic chuck (ESC) configured to support the substrate using an electrostatic force. Alternatively, the substrate-supporting module 200 may have other structures configured to support the substrate, for example, a mechanical clamping structure.

When the substrate-supporting module 200 may include the ESC, the substrate-supporting module 200 may include a dielectric layer 210, a focus ring 250 and a base 230. The substrate may be placed on an upper surface of the dielectric layer 210. Thus, the upper surface of the dielectric layer 210 may make contact with a lower surface of the substrate. The dielectric layer 210 may have a circular plate shape, but not limited thereto. The dielectric layer 210 may have a radius shorter than a radius of the substrate. The dielectric layer 210 may include a ceramic, but not limited thereto.

A lower electrode 212 may be arranged in the dielectric layer 210. A power source 240 may be connected to the lower electrode 212. The lower electrode 212 may receive an electrostatic force for fixing the substrate on the dielectric layer 210. The lower electrode 212 may include a mono polar electrode.

A heater 214 may be arranged in the dielectric layer 210 to heat the substrate. The heater 214 may be arranged under the lower electrode 212. The heater 214 may include a spiral coil, but not limited thereto.

The base 230 may be configured to support the dielectric layer 210. The base 230 may be positioned under the dielectric layer 210. The base 230 may be combined with the dielectric layer 210. A central portion of an upper surface of the base 230 may have a stepped structure protruded from an edge portion of the upper surface of the base 230. The central portion of the base 230 may have an area corresponding to an area of a bottom surface of the dielectric layer 210.

A cooling passage 232 may be formed in the base 230. A cooling fluid may flow through the cooling passage 232. The cooling passage 232 may have a spiral shape.

The base 230 may be connected to a high frequency power source 242 outside the process chamber 100. The high frequency power source 242 may apply power to the base 230. The power applied to the base 230 may guide the plasma in the process chamber 100 toward the base 230. The base 230 may include a metal.

The focus ring 250 may concentrate the plasma on the substrate. The focus ring 250 may be arranged on an edge portion of the upper surface of the dielectric layer 210. The focus ring 250 may have an annular shape configured to surround the substrate. The focus ring 250 may include silicon oxide, but not limited thereto. For example, the focus ring 250 may include other materials such as silicon carbide.

The focus ring 250 may be a single ring. Alternatively, the focus ring 250 may include a plurality of rings. For example, the focus ring 250 may include an inner ring and an outer ring surrounding the inner ring.

The gas-supplying module 300 may supply the process gases to the substrate on the substrate-supporting module 200. Particularly, the gas-supplying module 300 may rapidly supply the process gases into the process chamber 100. The gas-supplying module 300 may include a gas tank 350 and a plurality of gas lines 330. The gas tank 350 may be configured to store the process gases. The gas lines 330 may be connected to an upper surface of the process chamber 100.

The upper electrode module 500 may be arranged in an upper region of the process chamber 100. The upper electrode module 500 may include a gas block 550, an upper electrode 510, a distribution block 520, a gas distribution plate 530 and a showerhead 540.

The gas block 550 may be connected to the gas tank 350. For example, the gas lines 330 may be connected to the gas block 550. The gas block 550 may include a plurality of gas passages 552 connected to the gas lines 330.

The upper electrode 510 may be arranged under the gas block 550. Particularly, the upper electrode 510 may make contact with a lower surface of the gas block 550. A power source 400 may be connected to the upper electrode 510 to apply an RF power to the upper electrode 510. The upper electrode 510 may include a plurality of gas passages 512 connected to the gas passages 552 of the gas block 550.

The distribution block 520 may be arranged under the upper electrode 510. Particularly, the distribution block 520 may make contact with a lower surface of the upper electrode 510. The distribution block 520 may include a plurality of gas passages 522 connected to the gas passages 512 of the upper electrode 510.

The gas distribution plate 530 may be arranged under the distribution block 520. Particularly, the gas distribution plate 530 may make contact with a lower surface of the distribution block 520. The gas distribution plate 530 may include a plurality of gas passages 532 connected to the gas passages 522 of the distribution block 520.

The showerhead 540 may be arranged under the gas distribution plate 530. Particularly, the showerhead 540 may make contact with a lower surface of the gas distribution plate 530. The showerhead 540 may include a plurality of gas injection holes 542 connected to the gas passages 532 of the gas distribution plate 530. The process gases may be injected into the substrate-process region P of the process chamber 100 through the gas injection holes 542.

The valve module 800 may be configured to finally control the supply of the process gases into the substrate-processing region P of the process chamber 100 from the gas tank 550. In example embodiments, the valve module 800 may be arranged in the process chamber 100. Particularly, the valve module 800 may be provided below and in contact with the upper electrode module 500. Thus, the valve module 800 may be positioned adjacent to the substrate-processing region P to decrease a path of the process gases. Thus, a volume of the path and a flow resistance may be reduced so that the process gases used in a previous process may be rapidly exhausted from the apparatus 1000. As a result, process uniformity and productivity may be improved.

In example embodiments, the valve module 800 may be arranged on a lower surface of the showerhead 540. The valve module 800 may finally control the supply of the process gases from the gas injection holes 542 to the substrate-processing region P. The valve module 800 may be directly exposed to the substrate-processing region P. Thus, a distance between the valve module 800 and the substrate-processing region P. As a result, the path of the process gases (e.g., from the gas tank 350 to the substrate-processing region P) may be greatly shortened. Particularly, the time period in which the process gases traverse the path from the gas tank 350 to the substrate-processing region P may be decreased.

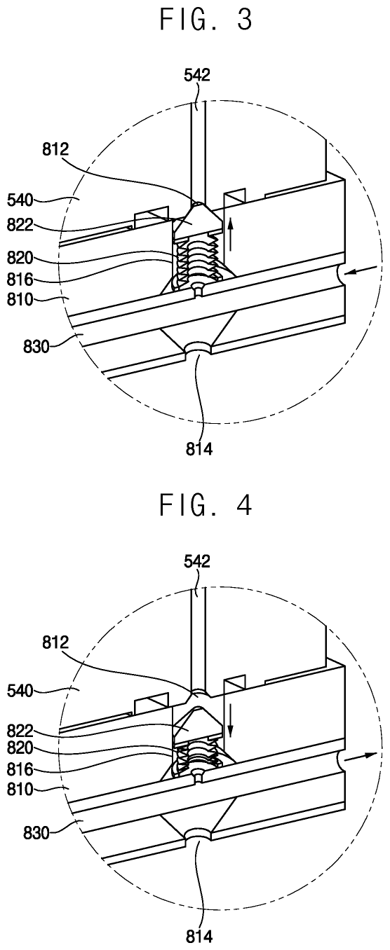

As illustrated in FIG. 3, the valve module 800 may include a valve block 810, a plurality of flexible valve stem 820 and a control line 830.

The valve block 810 may make contact with the lower surface of the showerhead 540. The valve block 810 may include a plurality of inlets 812, a plurality of outlets 814 and a plurality of gas passages 816.

The inlets 812 may be formed on an upper surface of the valve block 810. The inlets 812 may be connected to the gas injection holes 542 of the showerhead 540. Thus, the process gases may be introduced into the valve block 810 through the inlets 812.

The outlets 814 may be formed on a lower surface of the valve block 810. Thus, the outlets 814 may be directly exposed to the substrate-processing region P. The process gases may be injected to the substrate-processing region P through the outlets 814.

The gas passages 816 may be connected between the inlets 812 and the outlets 814. The process gases introduced through the inlets 812 may flow to the outlets 814 through the gas passages 816. Each of the gas passages 816 may have a width wider than a width of the inlet 812 and the outlet 814.

The flexible valve stem 820 may be arranged in the gas passage 816. The flexible valve stem 820 may be fixed to a bottom surface of the gas passage 816. The flexible valve stem 820 may be upwardly expanded by a working fluid in a vertical direction to selectively open and close the inlet 812, but not limited thereto. For example, the flexible valve stem 820 may selectively open and close the outlet 814. In example embodiments, the flexible valve stem 820 may include a bellows, but not limited thereto. For example, the flexible valve stem 820 may include various flexible materials expanded by the working fluid.

The control line 830 may be connected with the flexible valve stem 820 through the valve block 810. The working fluid may be supplied into the flexible valve stem 820 through the control line 830. Thus, as illustrated in FIG. 2 for example, a working fluid line 832 may be connected to the control line 830. As illustrated in FIG. 3 for example, when the working fluid is supplied into the flexible valve stem 820 through the control line 830, the flexible valve stem 820 may be upwardly expanded to close the inlet 812. In contrast, as illustrated in FIG. 4 for example, when the working fluid is discharged from the flexible valve stem 820, the flexible valve stem 820 may be downwardly contracted to open the inlet 812.

The valve module 800 may further include a resilient cap 822. The resilient cap 822 may be arranged on an upper end of the flexible valve stem 820. The resilient cap 822 may resiliently make contact with the inlet 812 to softly open and close the inlet 812.

Further, as illustrated in FIG. 2 for example, the valve module 800 may further include a vacuum line 834 and a three-way valve 840. The vacuum line 834 may be connected to the control line 830. The vacuum line 834 may provide the flexible valve stem 820 with vacuum for discharging the working fluid from the flexible valve stem 820. The three-way valve 840 may be arranged at a connected portion between the control line 830, the working fluid line 832 and the vacuum line 834. The three-way valve 840 may control the vacuum and the working fluid supplied to the flexible valve stem 820.

FIGS. 3 and 4 are perspective views illustrating an operation of the valve module in FIG. 2.

Referring to FIG. 3, the three-way valve 840 may open the working fluid line 832 and close the vacuum line 834. Thus, the working fluid may be supplied to the control line 830 through the three-way valve 840. The working fluid may be introduced into the flexible valve stem 820 so that the flexible valve stem 820 may be upwardly expanded by the working fluid. As a result, the resilient cap 822 on the flexible valve stem 820 may resiliently make contact with the inlet 812 to close the inlet 812.

Referring to FIG. 4, the three-way valve 840 may close the working fluid line 832 and open the vacuum line 834. Thus, the vacuum may be supplied to the control line 830 through the three-way valve 840. The working fluid may be discharged from the flexible valve stem 820 so that the flexible valve stem 820 may be downwardly contracted by the vacuum. As a result, the resilient cap 822 may be downwardly moved to open the inlet 812. The size of the flexible valve stem 820 and the resilient cap 822 may be configured such that process gases may flow from the inlet 812 to the outlet 814 when the flexible valve stem 820 is downwardly contracted by the vacuum and the resilient cap 822 is downwardly moved to open the inlet 812.

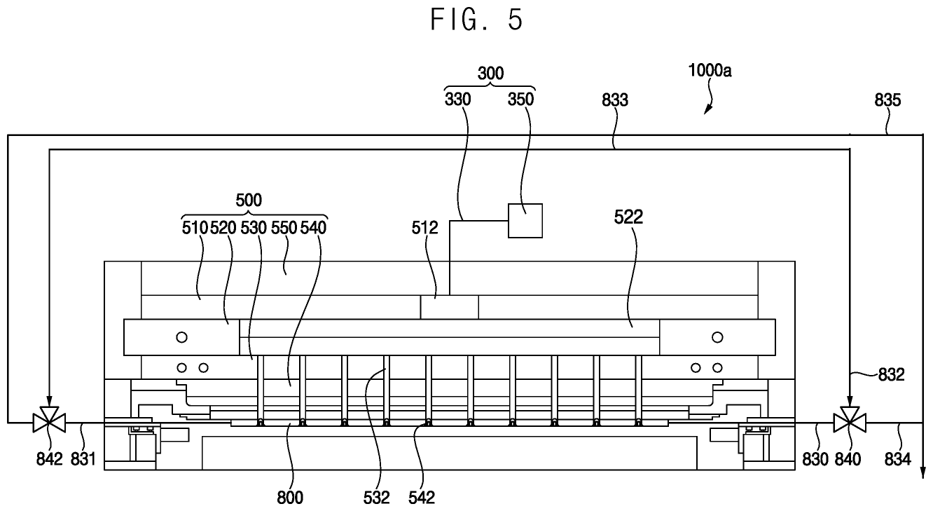

FIG. 5 is a cross-sectional view illustrating a valve module in accordance with example embodiments.

A valve module of an apparatus 1000a in accordance with example embodiments may include elements substantially the same as those of the valve module 800 in FIG. 2 except for further including a second control line, a first working fluid line and a second vacuum line. Thus, the same reference numerals may refer to the same elements and any further illustrations with respect to the same elements may be omitted herein for brevity.

Referring to FIG. 5, a first mixed gas and a second mixed gas among the process gases may be supplied to the substrate-processing region P through different paths. For example, the first mixed gas may be supplied to a left gas passage 816 among the gas passages 816 of the valve module 800. The second mixed gas may be supplied to a right gas passage 816 among the gas passages 816 of the valve module 800.

In this case, the control line 830 may be connected to the flexible valve stem 820 in the right gas passage 816. The working fluid line 832 and the vacuum line 834 may be connected to the control line 830. The three-way valve 840 may be positioned at the connected portion between the control line 830, the working fluid line 832 and the vacuum line 834. Thus, the three-way valve 840 may control the supply of the first mixed gas.

A second control line 831 may be connected to the flexible valve stem 820 in the left gas passage 816. A second working fluid line 833 may be branched from the working fluid line 832. The second working fluid line 833 may be connected to the second control line 831. A second vacuum line 835 may be branched from the vacuum line 834. The second vacuum line 835 may be connected to the second control line 831. A second three-way valve 842 may be installed at a connected portion between the second control line 831, the second working fluid line 833 and the second vacuum line 835. Thus, the second three-way valve 842 may control the supply of the second mixed gas.

In example embodiments, the two kinds of the mixed gases may be introduced into the valve module, but not limited thereto. When three kinds of mixed gases may be introduced into the valve module, the valve module may include at least three control lines, at least three working fluid lines and at least three vacuum lines.

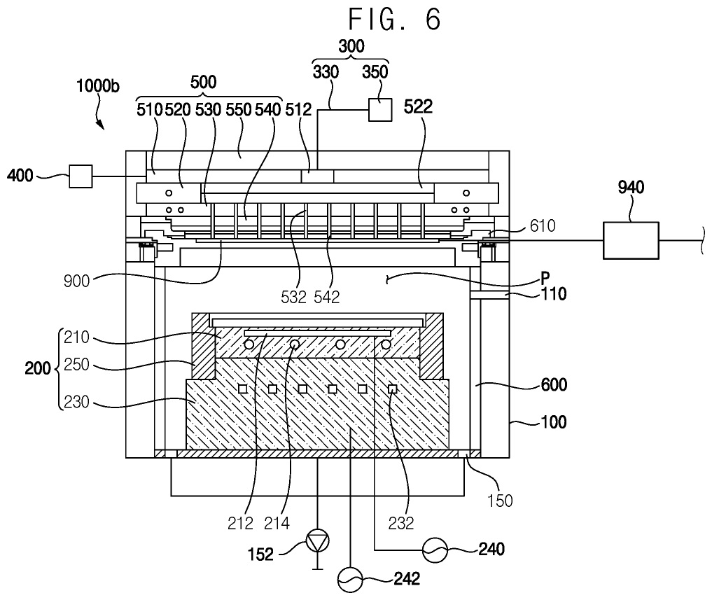

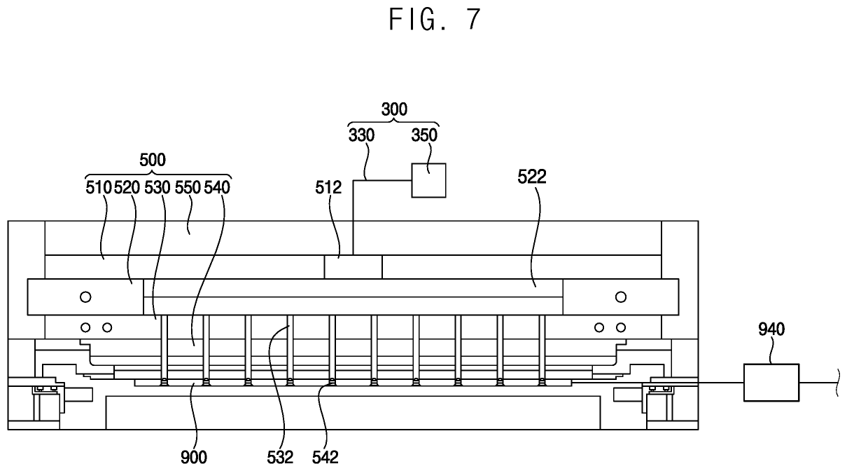

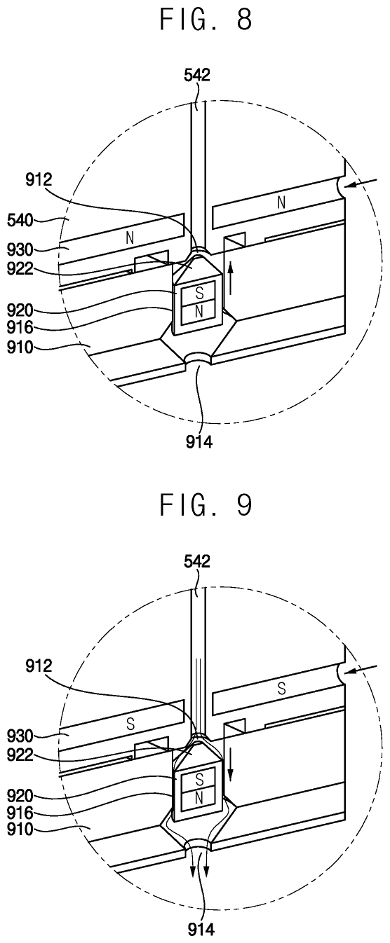

FIG. 6 is a cross-sectional view illustrating an apparatus for processing a substrate in accordance with example embodiments and FIG. 7 is an enlarged cross-sectional view illustrating a valve module provided to an upper electrode module of the apparatus in FIG. 6. FIGS. 8 and 9 are perspective views illustrating an operation of the valve module in FIG. 7

An apparatus 1000b of example embodiments may include elements substantially the same as those of the apparatus 1000 in FIG. 1 except for a valve module. Thus, the same reference numerals may refer to the same elements and any further illustrations with respect to the same elements may be omitted herein for brevity.

Referring to FIGS. 6-9, a valve module 900 of example embodiments may include a valve block 910, a plurality of permanent magnets 920 and an electromagnet 930. The electromagnet 930 may be selectively operated by a controller 940.

The valve block 910 may make contact with the lower surface of the showerhead 540. The valve block 910 may include a plurality of inlets 912, a plurality of outlets 914 and a plurality of gas passages 916.

The inlets 912 may be formed on the upper surface of the valve block 910. The inlets 912 may be connected to the gas injection holes 542 of the showerheads 540. Thus, the process gases may be introduced into the valve block 910 through the inlets 912.

The outlets 914 may be formed on the lower surface of the valve block 910. Thus, the outlets 914 may be directly exposed to the substrate-processing region P. The process gases may be injected to the substrate-processing region P through the outlets 914.

The gas passages 916 may be connected between the inlets 912 and the outlets 914. The process gases introduced through the inlets 912 may flow to the outlets 914 through the gas passages 916. Each of the gas passages 916 may have a width wider than a width of the inlet 912 and the outlet 914.

The permanent magnet 920 may be movably arranged in the gas passage 916 in the vertical direction. Each of the permanent magnets 920 may be arranged with the same polarity disposed in the same direction. For example, S polarities of the permanent magnets 920 may be upwardly oriented. N polarities of the permanent magnets 920 may be downwardly oriented. A resilient cap 922 may be arranged on an upper end of the permanent magnet 920.

The electromagnet 930 may be arranged in the valve block 910 adjacent to the permanent magnet 920. The electromagnet 930 may be selectively magnetized to the N polarity or the S polarity by the controller 940. Thus, when the electromagnet 930 is magnetized to the N polarity, an attractive force may be generated between the electromagnet 930 and the permanent magnet 920. In contrast, when the electromagnet 930 is magnetized to the S polarity, a repulsive force may be generated between the electromagnet 930 and the permanent magnet 920.

FIGS. 8 and 9 are perspective views illustrating an operation of the valve module in FIG. 2.

Referring to FIG. 8, when the electromagnet 930 is magnetized to the N polarity, the attractive force may be generated between the electromagnet 930 and the permanent magnet 920. Thus, the permanent magnet 920 may be upwardly moved by the attractive force to close the inlet 912 by the resilient cap 922.

Referring to FIG. 9, when the electromagnet 930 is magnetized to the S polarity, the repulsive force may be generated between the electromagnet 930 and the permanent magnet 920. Thus, the permanent magnet 920 may be downwardly moved by the repulsive force to open the inlet 912. The size of the permanent magnet 920 and the resilient cap 922 may be configured such that process gases may flow from the inlet 912 to the outlet 914 when the permanent magnet 920 (and the resilient cap 922 arranged on the upper end of the permanent magnet 920) is downwardly moved by the repulsive force to open the inlet 912.

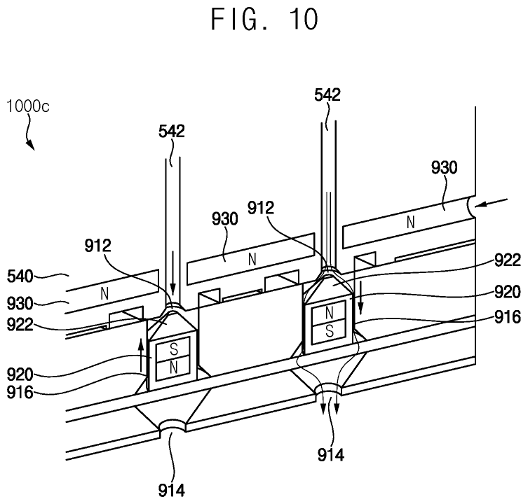

FIG. 10 is a cross-sectional view illustrating a valve module in accordance with example embodiments.

An apparatus 1000c of example embodiments may include elements substantially the same as those of the apparatus 1000 in FIG. 1 except for an arrangement of permanent magnets. Thus, the same reference numerals may refer to the same elements and any further illustrations with respect to the same elements may be omitted herein for brevity.

Referring to FIG. 10, a first mixed gas and a second mixed gas among the process gases may be supplied to the substrate-processing region P through the different paths. For example, the first mixed gas may be supplied to a left gas passage 916 among the gas passages 916 of the valve module 900. The second mixed gas may be supplied to a right gas passage 916 among the gas passages 916 of the valve module 900.

In this case, the S polarity of the left permanent magnet 920 may be upwardly oriented. In contrast, the N polarity of the right permanent magnet 920 may be upwardly oriented. When the electromagnet 930 is magnetized to the N polarity, the attractive force may be generated between the left permanent magnet 920 and the electromagnet 930. Thus, the left permanent magnet 920 may be upwardly moved by the attractive force so that the resilient cap 922 may close the left inlet 912. In contrast, when the electromagnet 930 is magnetized to the N polarity, the repulsive force may be generated between the right permanent magnet 920 and the electromagnet 930. Thus, the right permanent magnet 920 may be downwardly moved by the repulsive force so that the right inlet 912 may be opened. Alternatively, when the electromagnet 930 is magnetized to the S polarity, the left permanent magnet 920 may be downwardly moved so that the left inlet 912 may be opened and the right permanent magnet 920 may be upwardly moved so that the resilient cap 922 may close the right inlet 912.

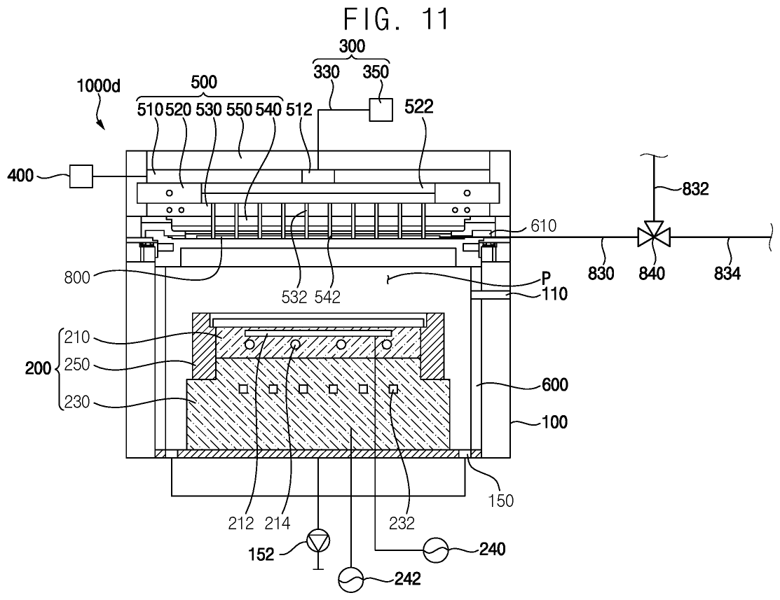

FIG. 11 is a cross-sectional view illustrating an apparatus for processing a substrate in accordance with example embodiments.

An apparatus 1000d of example embodiments may include elements substantially the same as those of the apparatus 1000 in FIG. 1 except for an arrangement of the valve module. Thus, the same reference numerals may refer to the same elements and any further illustrations with respect to the same elements may be omitted herein for brevity.

Referring to FIG. 11, the apparatus 1000d of example embodiments may include the valve module 800 as described with respect to FIG. 2. Alternatively, the apparatus 1000d of example embodiments may include the valve module 900 as described with respect to FIG. 7.

The valve module 800 may be arranged in the showerhead 540. For example, the valve module 800 and the showerhead 540 may be one body. Similarly, the valve module 900 may be arranged in the showerhead 540 such that the valve module 900 and the showerhead 540 may be one body.

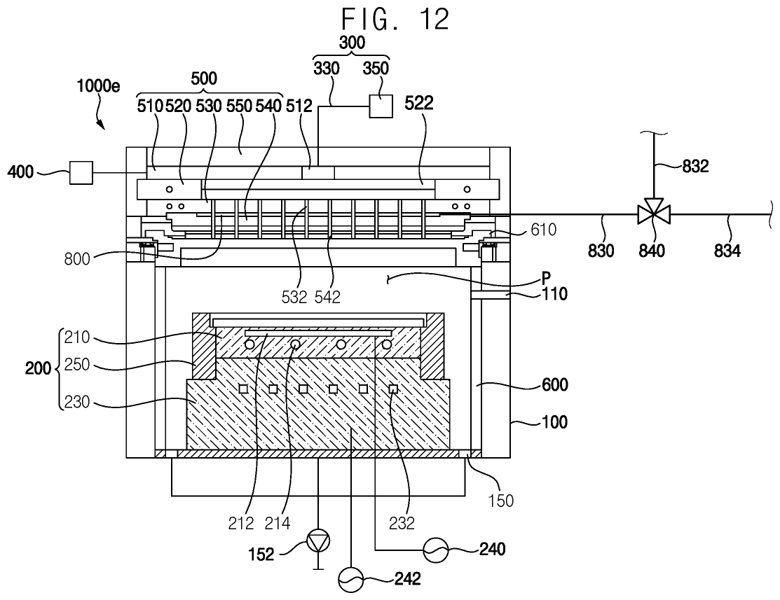

FIG. 12 is a cross-sectional view illustrating an apparatus for processing a substrate in accordance with example embodiments.

An apparatus 1000e of example embodiments may include elements substantially the same as those of the apparatus 1000 in FIG. 1 except for an arrangement of the valve module. Thus, the same reference numerals may refer to the same elements and any further illustrations with respect to the same elements may be omitted herein for brevity.

Referring to FIG. 12, the apparatus 1000e of example embodiments may include the valve module 800 as described with respect to FIG. 2. Alternatively, the apparatus 1000e of example embodiments may include the valve module 900 as described with respect to FIG. 7.

The valve module 800 may be arranged in an upper surface of the showerhead 540. For example, the lower surface of the valve module 800 may make contact with the upper surface of the showerhead 540. The upper surface of the valve module 800 may make contact with the lower surface of the gas distribution plate 530. Similarly, the valve module 900 may be arranged in the upper surface of the showerhead 540 such that the lower surface of the valve module 900 may make contact with the upper surface of the showerhead 540 and the upper surface of the valve module 900 may make contact with the lower surface of the gas distribution plate 530.

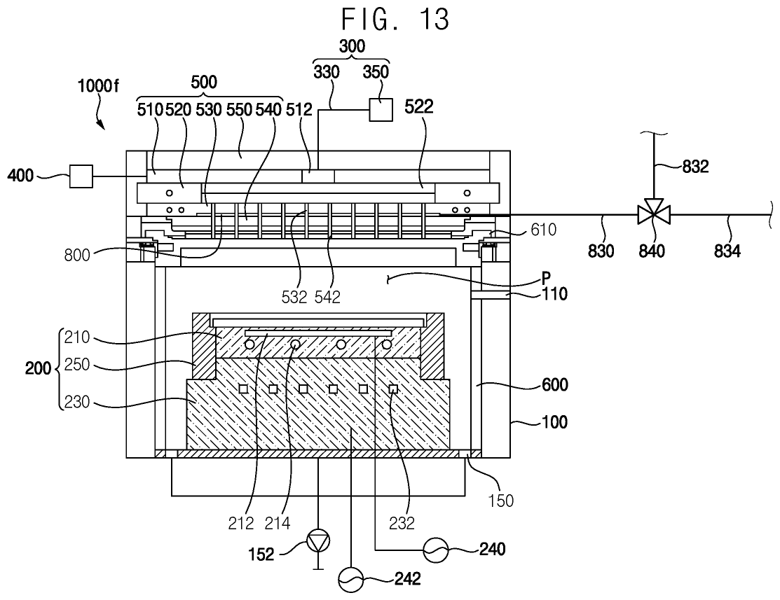

FIG. 13 is a cross-sectional view illustrating an apparatus for processing a substrate in accordance with example embodiments.

An apparatus 1000f of example embodiments may include elements substantially the same as those of the apparatus 1000 in FIG. 1 except for an arrangement of the valve module. Thus, the same reference numerals may refer to the same elements and any further illustrations with respect to the same elements may be omitted herein for brevity.

Referring to FIG. 13, the apparatus 1000f of example embodiments may include the valve module 800 as described with respect to FIG. 2. Alternatively, the apparatus 1000f of example embodiments may include the valve module 900 as described with respect to FIG. 7.

The valve module 800 may be arranged in the gas distribution plate 530. For example, the valve module 800 and the gas distribution plate 530 may be one body. Similarly, the valve module 900 may be arranged in the gas distribution plate 530 such that the valve module 900 and the gas distribution plate 530 may be one body.

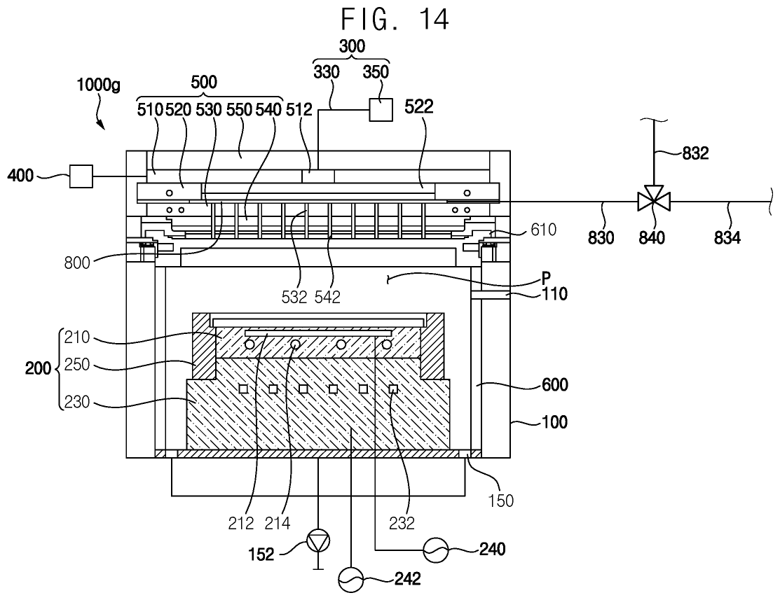

FIG. 14 is a cross-sectional view illustrating an apparatus for processing a substrate in accordance with example embodiments.

An apparatus 1000g of example embodiments may include elements substantially the same as those of the apparatus 1000 in FIG. 1 except for an arrangement of the valve module. Thus, the same reference numerals may refer to the same elements and any further illustrations with respect to the same elements may be omitted herein for brevity.

Referring to FIG. 14, the apparatus 1000g of example embodiments may include the valve module 800 as described with respect to FIG. 2. Alternatively, the apparatus 1000g of example embodiments may include the valve module 900 as described with respect to FIG. 7.

The valve module 800 may be arranged between the distribution block 520 and the gas distribution plate 530. For example, the lower surface of the valve module 800 may make contact with the upper surface of the gas distribution plate 530. The upper surface of the valve module 800 may make contact with the lower surface of the distribution block 520. Similarly, the valve module 900 may be arranged between the distribution block 520 and the gas distribution plate 530 such that the lower surface of the valve module 900 may make contact with the upper surface of the gas distribution plate 530 and the upper surface of the valve module 900 may make contact with the lower surface of the distribution block 520.

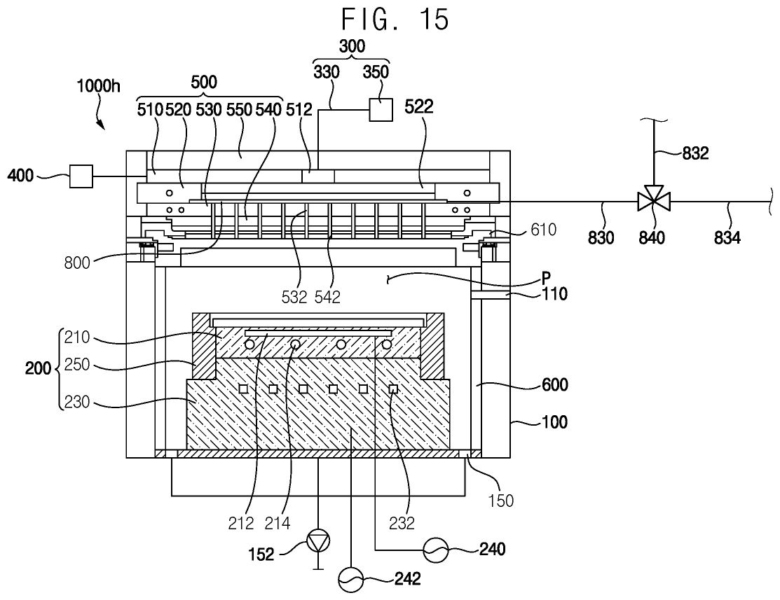

FIG. 15 is a cross-sectional view illustrating an apparatus for processing a substrate in accordance with example embodiments.

An apparatus 1000h of example embodiments may include elements substantially the same as those of the apparatus 1000 in FIG. 1 except for an arrangement of the valve module. Thus, the same reference numerals may refer to the same elements and any further illustrations with respect to the same elements may be omitted herein for brevity.

Referring to FIG. 15, the apparatus 1000h of example embodiments may include the valve module 800 as described with respect to FIG. 2. Alternatively, the apparatus 1000h of example embodiments may include the valve module 900 as described with respect to FIG. 7.

The valve module 800 may be arranged in the distribution block 520. For example, the valve module 800 and the distribution block 520 may be one body. Similarly, the valve module 900 may be arranged in the distribution block 520 such that the valve module 900 and the distribution block 520 may be one body.

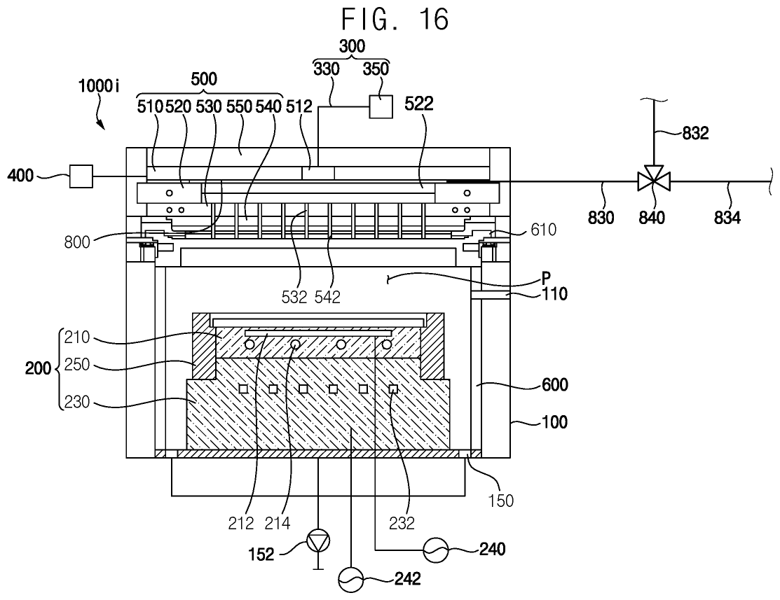

FIG. 16 is a cross-sectional view illustrating an apparatus for processing a substrate in accordance with example embodiments.

An apparatus 1000i of example embodiments may include elements substantially the same as those of the apparatus 1000 in FIG. 1 except for an arrangement of the valve module. Thus, the same reference numerals may refer to the same elements and any further illustrations with respect to the same elements may be omitted herein for brevity.

Referring to FIG. 16, the apparatus 1000i of example embodiments may include the valve module 800 as described with respect to FIG. 2. Alternatively, the apparatus 1000i of example embodiments may include the valve module 900 as described with respect to FIG. 7.

The valve module 800 may be arranged between the upper electrode 510 and the distribution block 520. For example, the lower surface of the valve module 800 may make contact with the upper surface of the distribution block 520. The upper surface of the valve module 800 may make contact with the lower surface of the upper electrode 510. Similarly, the valve module 900 may be arranged between the upper electrode 510 and the distribution block 520 such that the lower surface of the valve module 900 may make contact with the upper surface of the distribution block 520 and the upper surface of the valve module 900 may make contact with the lower surface of the upper electrode 510.

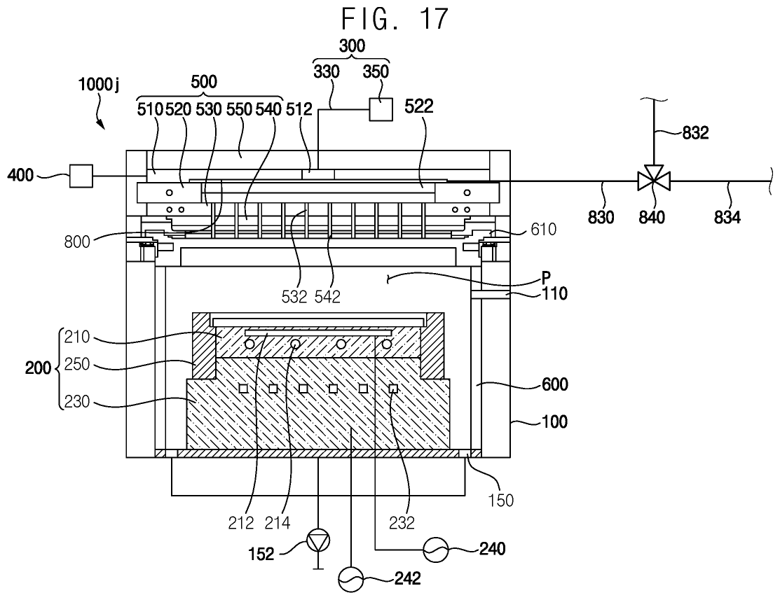

FIG. 17 is a cross-sectional view illustrating an apparatus for processing a substrate in accordance with example embodiments.

An apparatus 1000j of example embodiments may include elements substantially the same as those of the apparatus 1000 in FIG. 1 except for an arrangement of the valve module. Thus, the same reference numerals may refer to the same elements and any further illustrations with respect to the same elements may be omitted herein for brevity.

Referring to FIG. 17, the apparatus 1000j of example embodiments may include the valve module 800 as described with respect to FIG. 2. Alternatively, the apparatus 1000j of example embodiments may include the valve module 900 as described with respect to FIG. 7.

The valve module 800 may be arranged in the upper electrode 510. For example, the valve module 800 and the upper electrode 510 may be one body. Similarly, the valve module 900 may be arranged in the upper electrode 510 such that the valve module 900 and the upper electrode 510 may be one body.

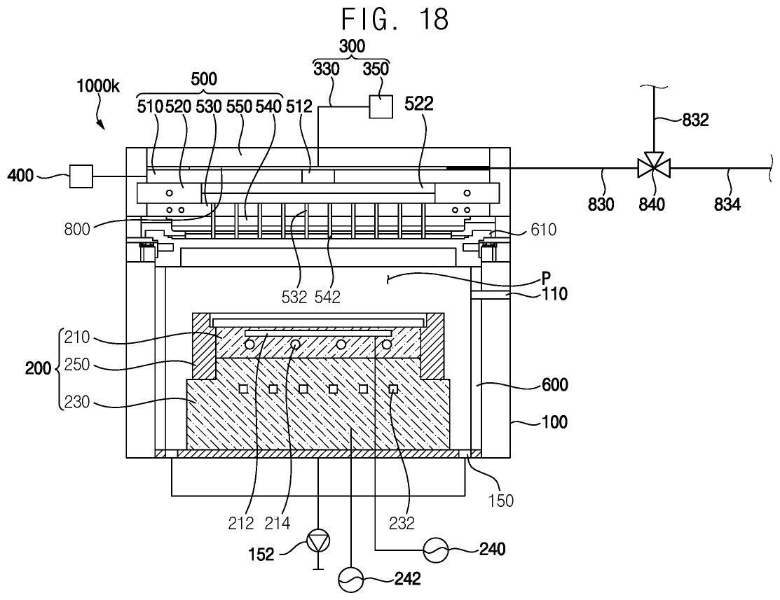

FIG. 18 is a cross-sectional view illustrating an apparatus for processing a substrate in accordance with example embodiments.

An apparatus 1000k of example embodiments may include elements substantially the same as those of the apparatus 1000 in FIG. 1 except for an arrangement of the valve module. Thus, the same reference numerals may refer to the same elements and any further illustrations with respect to the same elements may be omitted herein for brevity.

Referring to FIG. 18, the apparatus 1000k of example embodiments may include the valve module 800 as described with respect to FIG. 2. Alternatively, the apparatus 1000k of example embodiments may include the valve module 900 as described with respect to FIG. 7.

The valve module 800 may be arranged between the gas block 550 and the upper electrode 510. For example, the lower surface of the valve module 800 may make contact with the upper surface of the upper electrode 510. The upper surface of the valve module 800 may make contact with the lower surface of the gas block 550. Similarly, the valve module 900 may be arranged between the gas block 550 and the upper electrode 510 such that the lower surface of the valve module 900 may make contact with the upper surface of the upper electrode 510 and the upper surface of the valve module 900 may make contact with the lower surface of the gas block 550.

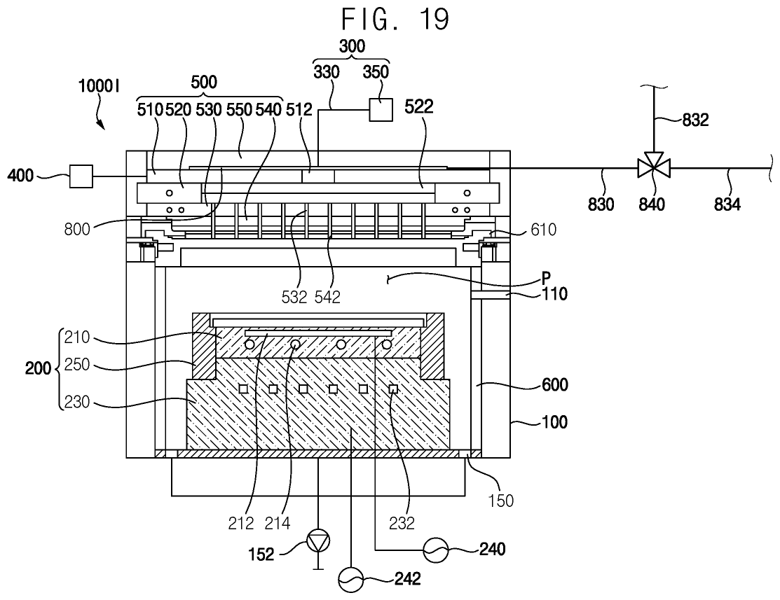

FIG. 19 is a cross-sectional view illustrating an apparatus for processing a substrate in accordance with example embodiments.

An apparatus 1000l of example embodiments may include elements substantially the same as those of the apparatus 1000 in FIG. 1 except for an arrangement of the valve module. Thus, the same reference numerals may refer to the same elements and any further illustrations with respect to the same elements may be omitted herein for brevity.

Referring to FIG. 19, the apparatus 1000l of example embodiments may include the valve module 800 as described with respect to FIG. 2. Alternatively, the apparatus 1000l of example embodiments may include the valve module 900 as described with respect to FIG. 7.

The valve module 800 may be arranged in the gas block 550. For example, the valve module 800 and the gas block 550 may be one body. Similarly, the valve module 900 may be arranged the gas block 550 such that the valve module 900 and the gas block 550 may be one body.

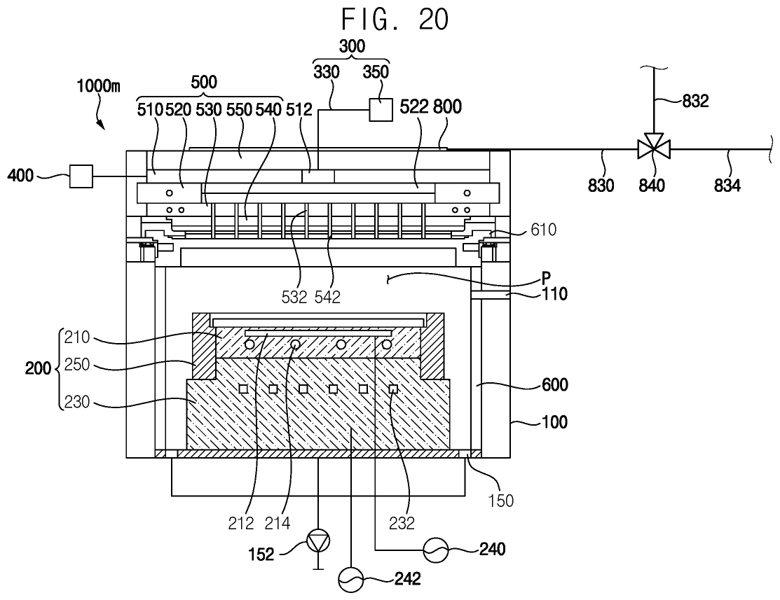

FIG. 20 is a cross-sectional view illustrating an apparatus for processing a substrate in accordance with example embodiments.

An apparatus 1000m of example embodiments may include elements substantially the same as those of the apparatus 1000 in FIG. 1 except for an arrangement of the valve module. Thus, the same reference numerals may refer to the same elements and any further illustrations with respect to the same elements may be omitted herein for brevity.

Referring to FIG. 20, the apparatus 1000m of example embodiments may include the valve module 800 as described with respect to FIG. 2. Alternatively, the apparatus 1000m of example embodiments may include the valve module 900 as described with respect to FIG. 7.

The valve module 800 may be arranged on the upper surface of the gas block 550. Thus, the process gases provided from the gas tank 530 may be first supplied to the valve module 800. Similarly, the valve module 900 may be arranged on the upper surface of the gas block 550 such that the process gases provided from the gas tank 530 may be first supplied to the valve module 900.

According to example embodiments, the valve module may be provided to the substrate-processing region of the apparatus, particularly, the upper electrode module. Thus, the length between the valve module and the apparatus, particularly, between the valve module and the substrate-processing region, i.e., the path of the process gases may be shortened. Particularly, the time period in which the process gases traverse the path of the process gases may be decreased. Thus, the volume of the path and the flow resistance may be reduced to rapidly exhaust the process gases used in a previous process from the apparatus. As a result, the process uniformity and the productivity may be improved.

The foregoing is illustrative of example embodiments and is not to be construed as limiting thereof. Although a few example embodiments have been described, those skilled in the art will readily appreciate that many modifications are possible in the example embodiments without droplet departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An apparatus for processing a substrate, the apparatus comprising:
a process chamber having a substrate-processing region using process gases;
a substrate-supporting module arranged in a lower region of the process chamber to support the substrate;
an upper electrode module arranged in an upper region of the process chamber; and
a valve module provided to the upper electrode module to control a supply of the process gases to the substrate-processing region.

2. The apparatus of claim 1, wherein the upper electrode module comprises:
a gas block configured to receive the process gases;
an upper electrode arranged under the gas block;
a distribution block arranged under the upper electrode;
a gas distribution plate arranged under the distribution block; and
a showerhead arranged under the gas distribution plate to inject the process gases to the substrate-processing region,
wherein the gas block, the upper electrode, the distribution block, the gas distribution plate and the showerhead include a plurality of gas passages through which the process gases flow.

3. The apparatus of claim 2, wherein the valve module is arranged on an upper surface of the gas block, between the gas block and the upper electrode, between the upper electrode and the distribution block, between the distribution block and the gas distribution plate, between the gas distribution plate and the showerhead, or on a lower surface of the showerhead.

4. The apparatus of claim 2, wherein the valve module is arranged in the gas block, the upper electrode, the distribution block, the gas distribution plate or the showerhead.

5. The apparatus of claim 1, wherein the valve module comprises:
a valve block including a plurality of inlets, a plurality of outlets and a plurality of gas passages, the inlets configured to receive the process gases, the outlets configured to inject the process gases to the substrate-processing region, and the gas passages connected between the inlets and the outlets;
a flexible valve stem arranged in each of the gas passages to open and close the inlet; and
a control line providing the flexible valve stem with a working fluid to expand the flexible valve stem toward the inlet.

6. The apparatus of claim 5, wherein the flexible valve stem comprises a bellows.

7. The apparatus of claim 5, wherein the valve module further comprises a resilient cap arranged on an upper end of the flexible valve stem to resiliently make contact with the inlet.

8. The apparatus of claim 5, wherein the valve module further comprises a vacuum line connected to the control line to provide the flexible valve stem with a vacuum for discharging the working fluid from the flexible valve stem.

9. The apparatus of claim 8, wherein the valve module further comprises a three-way valve arranged at a connected portion between the control line and the vacuum line to control supplies of the working fluid and the vacuum to the flexible valve stem.

10. The apparatus of claim 1, wherein the valve module comprises:
a valve block including a plurality of inlets, a plurality of outlets and a plurality of gas passages, the inlets configured to receive the process gases, the outlets configured to inject the process gases to the substrate-processing region, and the gas passages connected between the inlets and the outlets;
a permanent magnet movably arranged in each of the gas passages to open and close the inlet; and
an electromagnet configured to selectively apply a repulsive force and an attractive force to the permanent magnet.

11. The apparatus of claim 10, wherein the permanent magnet in any one of the gas passages has a polarity different from a polarity of the permanent magnet in other gas passage.

12. An apparatus for processing a substrate, the apparatus comprising:
a process chamber having a substrate-processing region using process gases;
a substrate-supporting module arranged in a lower region of the process chamber to support the substrate;
an upper electrode module arranged in an upper region of the process chamber; and
a valve module provided to the upper electrode module to control a supply of the process gases to the substrate-processing region,
wherein the valve module comprises:
a valve block including a plurality of inlets, a plurality of outlets and a plurality of gas passages, the inlets configured to receive the process gases, the outlets configured to inject the process gases to the substrate-processing region, and the gas passages connected between the inlets and the outlets;
a flexible valve stem arranged in each of the gas passages to open and close the inlet; and
a control line providing the flexible valve stem with a working fluid to expand the flexible valve stem toward the inlet.

13. The apparatus of claim 12, wherein the upper electrode module comprises:
a gas block configured to receive the process gases;
an upper electrode arranged under the gas block;
a distribution block arranged under the upper electrode;
a gas distribution plate arranged under the distribution block; and
a showerhead arranged under the gas distribution plate to inject the process gases to the substrate-processing region,
wherein the gas block, the upper electrode, the distribution block, the gas distribution plate and the showerhead include a plurality of gas passages through which the process gases flow.

14. The apparatus of claim 13, wherein the valve module is arranged on an upper surface of the gas block, between the gas block and the upper electrode, between the upper electrode and the distribution block, between the distribution block and the gas distribution plate, between the gas distribution plate and the showerhead, or on a lower surface of the showerhead.

15. The apparatus of claim 13, wherein the valve module is arranged in the gas block, the upper electrode, the distribution block, the gas distribution plate or the showerhead.

16. The apparatus of claim 12, wherein the flexible valve stem comprises a bellows.

17. The apparatus of claim 12, wherein the valve module further comprises a resilient cap arranged on an upper end of the flexible valve stem to resiliently make contact with the inlet.

18. The apparatus of claim 12, wherein the valve module further comprises:
a vacuum line connected to the control line to provide the flexible valve stem with a vacuum for discharging the working fluid from the flexible valve stem; and
a three-way valve arranged at a connected portion between the control line and the vacuum line to control supplies of the working fluid and the vacuum to the flexible valve stem.

19. An apparatus for processing a substrate, the apparatus comprising:
a process chamber having a substrate-processing region using process gases;
a substrate-supporting module arranged in a lower region of the process chamber to support the substrate;
an upper electrode module arranged in an upper region of the process chamber; and
a valve module provided to the upper electrode module to control a supply of the process gases to the substrate-processing region,
wherein the valve module comprises:
a valve block including a plurality of inlets, a plurality of outlets and a plurality of gas passages, the inlets configured to receive the process gases, the outlets configured to inject the process gases to the substrate-processing region, and the gas passages connected between the inlets and the outlets;
a permanent magnet movably arranged in each of the gas passages to open and close the inlet; and
an electromagnet configured to selectively apply a repulsive force and an attractive force to the permanent magnet.

20. The apparatus of claim 19, wherein the permanent magnet in any one of the gas passages has a polarity different from a polarity of the permanent magnet in other gas passage.
